(19) United States
(12) Patent Application Publication
(10) Pub. No.: US 2026/0036622 A1
(43) Pub. Date: Feb. 5, 2026

(54) METHOD AND DEVICE FOR TESTING APPLICATIONS EMBEDDED IN ELECTRONIC SYSTEMS

(71) Applicant: STMicroelectronics International N.V., Geneva (CH)

(72) Inventors: Alexis Masson, Le Mans (FR); Samuel Brillet, Bonchamp (FR)

(21) Appl. No.: 19/258,252

(22) Filed: Jul. 2, 2025

(30) Foreign Application Priority Data
Aug. 5, 2024 (FR) FR2408639

(51) Int. Cl. G01R 31/317; G01R 31/319

(52) U.S. Cl. CPC G01R 31/31713; G01R 31/31703; G01R 31/31907

(57) ABSTRACT

A testing device comprises at least one first communication interface for receiving data from an electronic system to be tested and transmitting data to the electronic system, at least one second communication interface, distinct from the first communication interface, for transmitting data to a test computer of the electronic system, the testing device being configured to receive at least one item of data from the electronic system and/or transmit at least one item of data to the electronic system, via a first communication bus connected to the first interface, autonomously, and being configured to transmit, via a second communication bus connected to the second interface, at least one item of data representative of at least one item of data received and/or of at least one item of data transmitted via the first communication bus.

### CROSS-REFERENCE TO RELATED APPLICATIONS

This application claims the benefit of French Application No. FR2408639, filed on Aug. 5, 2024, which application is hereby incorporated herein by reference.

### TECHNICAL FIELD

Embodiments relate to the field of testing electronic systems, in particular testing applications embedded in electronic systems used according to a mode of the master or controller type, comprising rapid communication buses, more particularly testing drivers, using standard computers.

### BACKGROUND

As programmable electronic systems are increasingly complex and, often, increasingly generic, they are used in many contexts and undergo regular, particularly software, updates. These systems are generally provided with one or more buses for receiving and/or transmitting data, for example to obtain data from sensors and/or control actuators.

### SUMMARY

There is a need for tests to check that the behavior of applications embedded in these electronic systems, for using the latter in new situations or new configurations, is in line with expectations. In order to test such applications, comprising transmitting or receiving data, the communication bus(es) of the system tested are connected to operational communication elements, capable of interacting in accordance with the specificities of the bus used, particularly in terms of response time and protocol.

In order to test an application embedded in an electronic system, the application is loaded into this electronic system then executed and a distinct system, for example a test management computer, analyzes the behavior of the electronic system tested, particularly at the level of data exchanges on the communication bus(es).

However, the presence of real-time communication buses or of low latency in the electronic systems to be tested, for example buses of the I2C (acronym for Inter-Integrated Circuit), SPI (acronym for Serial Peripheral Interface) or UART (acronym for Universal Asynchronous Receiver Transmitter) type, does not make it possible to carry out tests in real time with a standard computer of the personal type, for example for carrying out a test scenario.

Indeed, a standard computer executing a test scenario is too slow in relation to a communication bus of the I2C, SPI or UART type.

Therefore, there is a need for a simple testing solution to be implemented, that is sufficiently generic to be usable in many contexts and that may be able to carry out a large number of tests autonomously. This solution makes it possible to test the behavior of an application embedded in an electronic device receiving and/or transmitting data via a real-time or low latency communication bus, for example buses of the I2C, SPI or UART type, particularly according to a communication mode of the “master” or “controller” type (i.e. according to which the electronic device tested initiates the transmission and/or the reception of data).

According to one aspect, a testing device is proposed comprising at least one first communication interface for receiving data from an electronic system to be tested and transmitting data to the electronic system, at least one second communication interface, distinct from the first communication interface, for transmitting data to a test computer of the electronic system, the testing device being configured to receive at least one item of data from the electronic system and/or to transmit at least one item of data to the electronic system, via a first communication bus connected to the first interface, autonomously, and being configured to transmit, via a second communication bus connected to the second interface, at least one item of data representative of at least one item of data received and/or of at least one item of data transmitted via the first communication bus.

Such a device makes it possible to carry out a large number of tests, without manual intervention, on an application embedded in an electronic device.

According to some embodiments, the item of received data is a request, the testing device being configured to transmit the at least one item of data to the electronic system in response to the request.

According to some embodiments, the testing device comprises a memory for storing the at least one item of data to be transmitted and a data processing unit for determining at least one item of data to be transmitted from.

According to some embodiments, the device further comprises a selector for transmitting the at least one item of received data to the electronic system via the first communication bus.

According to another aspect, an integrated assembly is proposed comprising the testing device described above and an electronic system to be tested.

Such a device makes it possible to carry out a large number of tests, without manual intervention, on an application embedded in the electronic device.

According to yet another aspect, a method for testing an application embedded in an electronic system is proposed, the electronic system being connected, via a first communication bus, to a testing device as previously described, the testing device further being connected to a test computer via a second communication bus distinct from the first communication bus, the method being implemented in the testing device and comprising detecting an event for transmitting at least one item of data to the electronic system via the first communication bus and determining the at least one item of data to be transmitted, transmitting, to the electronic system, the at least one item of data via the first communication bus, and transmitting, to the test computer, via the second communication bus, at least one item of data representative of at least one item of data received from the electronic system via the first communication bus and/or at least one item of data transmitted to the electronic system via the first communication bus.

Such a method makes it possible to carry out a large number of tests, without manual intervention, on an application embedded in an electronic device. Such a test method may aim to interact at any moment of the development cycle of the electronic system (e.g., debugging, prototyping, etc.).

Still according to another aspect, a method for testing an application embedded in an electronic system is proposed, the electronic system being connected, via a first communication bus, to a testing device as described above, the method being implemented in a test computer connected to the testing device via a second communication bus and comprising transmitting, to the testing device, at least one configuration instruction to transmit at least one item of data to the electronic system, the at least one instruction comprising at least one selection indication to select the at least one item of data to be transmitted to the electronic system via the first communication bus, and transmitting, to the testing device, at least one read instruction to receive, via the second communication bus, at least one item of data representative of at least one item of data received from the electronic system via the first communication bus and/or at least one item of data transmitted to the electronic system via the first communication bus.

Such a method makes it possible to carry out a large number of tests, without manual intervention, on an application embedded in an electronic device.

According to some embodiments, the transmission of at least one read instruction is repeated according to a test scenario of the embedded application.

Still according to some embodiments, the transmission of at least one configuration instruction is carried out before the repeated transmission of read instructions.

Still according to some embodiments, the method further comprises receiving the at least one item of data representative of at least one item of data received from the electronic system via the first communication bus and/or at least one item of data transmitted to the electronic system via the first communication bus and comparing the at least one item of data representative of at least one item of data received from the electronic system via the first communication bus and/or at least one item of data transmitted to the electronic system via the first communication bus with an expected item of data.

### BRIEF DESCRIPTION OF THE DRAWINGS

Other advantages and features will become apparent upon examining the detailed description of non-limiting embodiments and implementations, and from the appended drawings, wherein:

FIG. 1 illustrates a test environment comprising an electronic system embedding an application to be tested, a test computer, and a testing device;

FIG. 2 illustrates an example architecture of the testing device;

FIG. 3 illustrates a time chart of one example of testing of an application embedded in the electronic system;

FIG. 4 illustrates an example of implementation steps in the test computer for testing an application embedded in the electronic system;

FIG. 5a illustrates an example of implementation steps in the testing device to test an application embedded in the electronic system;

FIG. 5b illustrates a routine comprising identifying particular conditions or events; and

FIG. 6 illustrates one example of a test computer that may implement a method according to particular embodiments.

### DETAILED DESCRIPTION OF ILLUSTRATIVE EMBODIMENTS

According to some embodiments, a test environment of an application to be tested, embedded in an electronic system, comprises a test computer configured to execute a test scenario and a testing device configured to exchange data with the electronic system, according to features of a communication bus of the latter. Data representative of data received from the electronic system, by the testing device, and/or data transmitted, to the electronic system, by the testing device are stored in the testing device and may be transmitted to the test computer, independently of data exchanges between the electronic system and the testing device. Thus, the test computer can access the test data without having to interact directly with the communication bus of the electronic system. The test computer is for example a computer of the PC type, a server, an embedded system, etc., that may also be called controller or orchestrator.

FIG. 1 schematically illustrates a test environment 100 comprising an electronic system 105 embedding an application to be tested, also called DUT (acronym for Device Under Test), a test computer 110 and a testing device 115.

As illustrated, the electronic system 105 is connected to the testing device 115 by a first communication bus 120, for example a communication bus of the I2C (acronym for Inter-Integrated Circuit), SPI (acronym for Serial Peripheral Interface) or UART (acronym for Universal Asynchronous Receiver Transmitter) type. The electronic system 105 here is of the “master” or “controller” type, that is to say it initiates the transmission and/or the reception of data on the communication bus 120. The testing device 115 is configured to receive and/or transmit data on the communication bus 120, according to the protocol of the latter, and to respond to the requests of the electronic system 105. Thus, the testing device makes it possible to test the application embedded in the electronic system 105 when it uses this bus (by checking that the accesses to the bus are in line with expectations).

In addition as illustrated, the testing device 115 is moreover connected to the test computer 110 by a second communication bus 125, distinct from the first communication bus, for example a communication bus of the USB (acronym for Universal Serial Bus) type. Thus, the test computer 110 can configure the testing device 115, for example to indicate thereto how to respond to the requests from the electronic system 105 on the communication bus 120 and to access data stored in the testing device 115. The stored data are for example data representative of data received from the electronic system, by the testing device, and/or data transmitted, to the electronic system, by the testing device. They are stored in the testing device and can be transmitted to the test computer, via the second communication bus 125, independently of the transmission and/or reception of these data via the first communication bus 120.

Finally, according to particular embodiments, the electronic system 105 is connected to the test computer 110 by a third communication bus 130, for example a communication bus of the USB type. The communication bus 130 can particularly be used prior to testing the application embedded in the electronic system 105, for example in order to load the application and initialize the electronic system 105.

Here, it is observed that the electronic system 105 and the testing device 115 may be distinct elements, may be mounted on the same board or may be integrated in the same circuit, for example in the form of an SoC (acronym for System on a Chip).

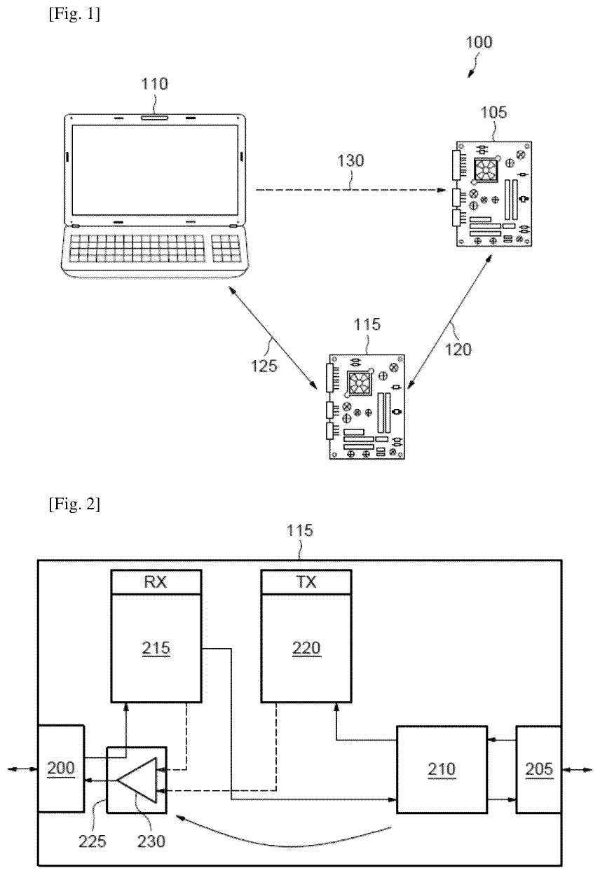

FIG. 2 schematically illustrates one example of architecture of the testing device 115.

As illustrated, here the testing device 115 comprises a first interface 200 towards the first communication bus 120, for example of the I2C, SPI or UART type, and a second interface 205 towards the second communication bus 125, for example of the USB type. These interfaces make it possible to receive and/or transmit data according to a determined protocol linked to the bus type used. The testing device 115 also comprises a data processing unit 210, for example to analyze commands received via the interface 205, configure the testing device according to commands received, select data to be transmitted on the first communication bus and/or on the second communication bus, etc.

The testing device 115 further comprises a receive buffer 215 (or a receive buffer area) for storing data received via the first interface 200. According to particular embodiments, it also comprises a transmission buffer 220 (or a transmission buffer area) for storing data received via the second interface 205, to be transmitted via the first interface 200. By way of illustration, the buffer memory areas 215 and 220 may belong to the same memory element, for example of the RAM (acronym for random memory access) type, but with different addresses, or with different memory elements. Still according to particular embodiments, the testing device 115 comprises an agent 225 itself comprising a selector 230 for using the receive buffer 215 or the transmission buffer 220 as source of data to be transmitted via the first interface 200. The agent 225 also makes it possible to identify the data received via the first interface 200, to be stored in the receive buffer 215. Here, it is configured or implemented by the data processing unit 210.

As illustrated, the write access of the receive buffer 215 is connected to the first interface 200, via the agent 225, and the read access thereof is connected to the data processing unit 210. Thus, the latter can transfer data received via the first interface and stored in this memory towards the second communication bus, via the second interface 205. According to particular embodiments, the read access of the receive buffer 215 is further connected to the selector 230. According to other embodiments, for example in the absence of transmission buffer 220, the read access of the receive buffer 215 is connected directly to the first interface 200, via the agent 225, without using a selector.

In addition as illustrated, the write access of the transmission buffer 220 is connected to the data processing unit 210 and the read access thereof is connected to the selector 230. According to other embodiments, for example if the read access of the receive buffer 215 is only connected to the data processing unit 210, the read access of the transmission buffer 220 is connected directly to the first interface 200, via the agent 225, without using a selector.

Thus, the testing device 115 makes it possible to interact in real time with the first communication bus and to transmit, in non-real time, towards the second communication bus, data relating to this interaction.

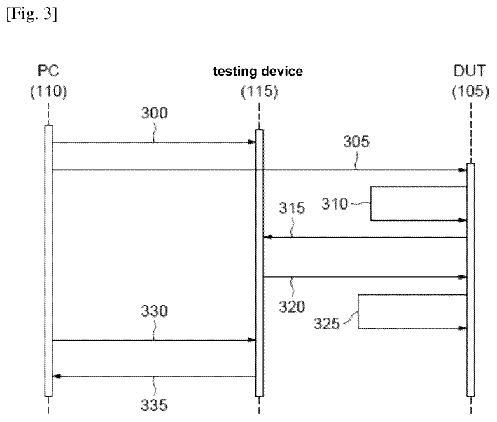

FIG. 3 schematically illustrates a time chart of one example of testing of an application embedded in the electronic system 105, with the aid of a test computer 110, here of the PC (acronym for Personal Computer) type, and of a testing device 115.

As illustrated, here the object of a first step (step 300) is to transmit, by the test computer 110 to the testing device 115, a test configuration command 300. Here, this command is transmitted via the second communication bus 125, for example of the USB type. This step particularly comprises configuring the behavior of the testing device in order to emit data on the communication bus connecting it to the test system, for example in order to transmit an item of data in response to a request, and initializing this communication bus. The transmitted data may be predetermined data, data received in advance from the electronic system, etc.

In a following step (step 305), the test computer 110 transmits to the electronic system 105 the program to be executed and an initialization instruction. After loading, the electronic system 105 executes the application. Some steps do not use the communication bus (e.g. step 310) whereas the object of other steps is to transmit data or to obtain data. By way of illustration, step 315 is a request to obtain data. This request is transmitted by the electronic system 105, via the first communication bus 120. In response to this request, the testing device 115 transmits to the electronic system 105, via the first communication bus 120, an item of data (step 320). According to some embodiments, the response is in line with the standard, particularly in terms of format and of response time, and with the expectations of the application to be tested (the latter imposes the content of the response and the maximum time limit). The content thereof, linked to the configuration of the testing device, may be any or correspond to a scenario controlled by the test computer. It may particularly concern a predetermined item of data or an item of data received from the electronic system 105.

The execution of the application continues (step 325) with or without other data exchanges.

At the same time as the execution of the application in the electronic system tested, the test computer may query the testing device (step 330), for example to obtain data exchanged between the testing device 115 and the electronic system 105 or data representative of the data exchanged. The exchanged data may be the data transmitted by the testing device to the electronic system and the data transmitted by the electronic system to the testing device, only the data transmitted by the testing device to the electronic system, only the data transmitted by the electronic system to the testing device or some of these data.

In response to the request from the test computer received by the second communication bus, the testing device transmits the requested data, stored in the internal memory, to the test computer, via the same bus (step 335).

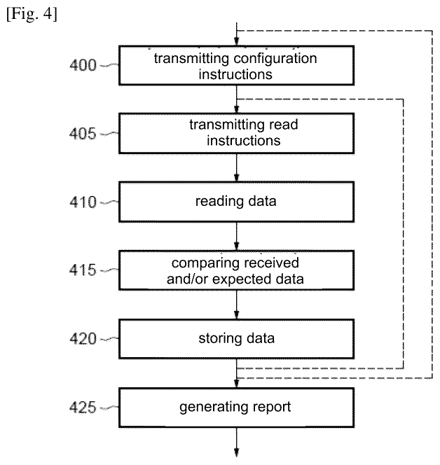

FIG. 4 illustrates an example of implementation steps in the test computer 110 for testing an application embedded in the electronic system 105.

As illustrated, the object of a first step (step 400) is to transmit a command for configuring a testing device. As described above, this command particularly comprises configuring the communication interface towards this communication bus (e.g. the interface 200 in FIG. 2).

According to some particular embodiments, the command for configuring the testing device further indicates to the testing device how to interact with the electronic system to which it is connected by a communication bus, for example in which conditions to transmit data and/or how to determine the data to be transmitted.

Still according to some particular embodiments, the step of transmitting a configuration command comprises a step of transmitting a data write command, in order to store data in the testing device, these data potentially being transmitted later, according to particular conditions, to the electronic system. According to other embodiments, the transmission of data write commands is carried out independently of the transmission of configuration commands.

In a following step (step 405), the test computer sends a read command to the testing device to obtain data exchanged between the electronic system and the testing device or data representative of these exchanged data. As described above, the exchanged data are the data transmitted by the electronic system to the testing device and the data transmitted by the testing device to the electronic system, only the data transmitted by the electronic system to the testing device, only the data transmitted by the testing device to the electronic system or some of these data.

In response, the test computer receives the requested data (step 410) that may be compared with expected data (step 415). The received data and, if applicable, the expected data and/or the result of the comparison between the requested data and the expected data are stored to enable a posteriori analysis (step 420). The stored data are for example the received data and context data, for example linked to the test scenario.

As illustrated, other data can be obtained in the same way and/or the testing device can be reconfigured to carry out other tests.

After all of the tests have been carried out (or as and when they are carried out), a test report can be generated (step 425).

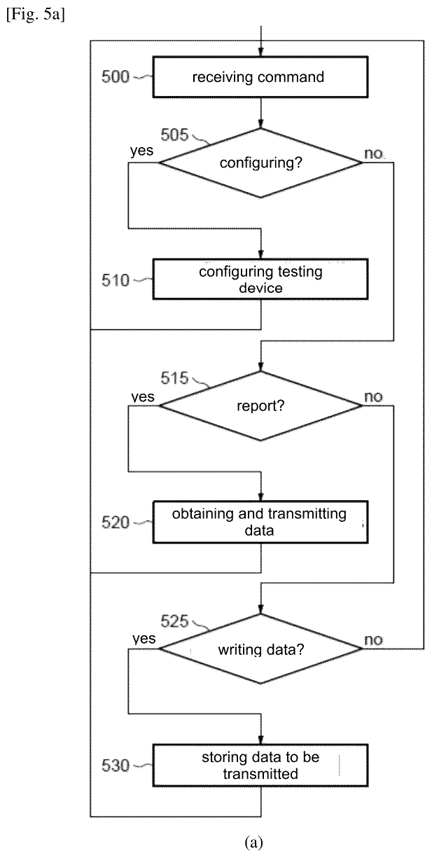

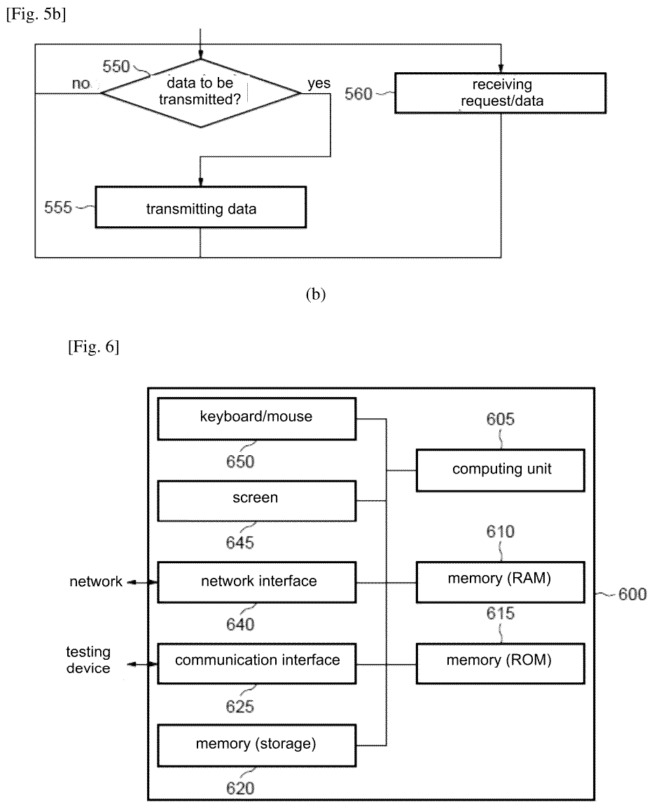

FIG. 5a illustrates an example of implementation steps in the testing device 115 to test an application embedded in the electronic system 105.

As illustrated, the object of a first step (step 500) is to receive a command. This command may be received by a test computer. After receiving a command, a test is carried out to determine whether the received command is a command for configuring the testing device (step 505), for example in order to indicate to the testing device how to interact with the electronic system to which it is connected by a communication bus. According to some embodiments, this command also comprises configuring the interface of this communication bus.

After receiving the command and if the received command is a configuration command, the testing device is configured according to the received command (step 505). For example, in relation to FIG. 2, the data processing unit 210 configures the first interface 200 and the agent 225.

If the received command is not a configuration command, here a test is carried out to determine whether the received command is a command to read data stored in the testing device, that is to say a command to obtain an execution report (step 515). If a command to obtain an execution report is received, the corresponding data are transmitted (step 520). According to particular embodiments, the data to be transmitted are determined during the configuration of the testing device. According to other embodiments, the data to be transmitted are indicated in the command for reading and obtaining data. For example, in relation to FIG. 2, the data processing unit 210 reads the requested data in the receive buffer 215 and transmits it.

If the received command is neither a configuration command nor a command to obtain an execution report, here a test is carried out to determine whether the received command is a command to write data, for example data to be stored in order to be transmitted to the electronic system (step 525). If a data read command is received, for example with the data to be stored, the data are stored (step 530). For example, in relation to FIG. 2, the data processing unit 210 stores the received data in the transmission buffer 220.

After having configured the testing device, read data or stored data or if the received command is, according to this example, neither a configuration command, nor a command to obtain an execution report, nor a data write command, the algorithm loops on itself to process new commands until it is ended.

The steps described in FIG. 5a are for example implemented in the data processing unit 210 in FIG. 2 with which a memory may be associated in order to store instructions to be executed, temporary variables and data to be processed or processed, as described with reference to FIG. 6.

At the same time and independently of the steps of processing received commands, the testing device executes a routine (for example the agent 225 in FIG. 2) to determine whether conditions for transmitting data are met or whether a particular event that triggers the transmission of data is detected and, if applicable to determine the data to be transmitted to the electronic system by the communication bus connecting the testing device to the electronic system. According to particular embodiments and as illustrated in FIG. 5b, this routine may comprise identifying particular conditions or events (step 550), for example receiving, from the electronic system, a request to obtain data (step 560). If data are to be transmitted, they are transmitted (step 555). As described above, data to be transmitted may particularly be predetermined data or data received in advance from the electronic system. The conditions for transmitting data and/or the parameters for determining data to be transmitted may be linked to the configuration of the testing device, may be preconfigured in the testing device with the possibility of modifying the configuration or may be defined, without possibility of modification, in the testing device.

The steps described in FIG. 5b are for example implemented in a dedicated data processing unit or in the data processing unit 210 in FIG. 2, in the form of an independent process of the process described with reference to FIG. 5a.

FIG. 6 illustrates one example of a test computer that may implement a method according to particular embodiments, particularly the methods illustrated in FIGS. 3 and 4. The computer 600 is for example an embedded computer of the PC (acronym for personal computer) type.

As illustrated, the computer 600 comprises one or more internal communication buses, shared or not, to which are connected a central processing unit 605 (CPU), a random access memory 610 (RAM) including registers adapted to save variables and parameters created and modified during the execution of the programs implementing the steps described above, a read only memory 615 (ROM) that may include an operating system and programs implementing the steps described above, a storage support 620, fixed or removable, that may particularly be used for storing instructions and/or data to be processed or processed, and a communication interface 625, for connecting with a testing device.

The computer 600 further comprises, preferably, a network interface 640 connected to a communication network, for example a wireless communication network and/or a local communication network, the interface being capable of transmitting and receiving data, particularly to and from another of the servers, computers, tablets and/or smartphones. The communication interface 640 is for example in line with one of the Bluetooth, WiFi, 3G, 4G, 5G, 6G, etc., standards.

The computer 600 may also have a screen 645, particularly a touch display making it possible for a user to interact with programs implemented by the computer 600, and input means 650 such as a keyboard and/or a mouse making it possible for the user to interact with programs implemented by the computer 600.

The internal communication bus makes the communication and the interoperability possible between the various elements included in the computer 600 or connected thereto. The representation of the internal communication bus is not limiting and, in particular, the central processing unit is likely to communicate instructions to any element of the computer 600 directly or by means of another element of the computer 600.

As the executable code of the programs makes it possible for the computer 600 to implement, totally or partially, the method according to an embodiment, may be stored, for example, in the read only memory 615. According to an alternative embodiment, the executable code of the programs may be received by means of the communication network, via the interface 640, to be stored in a manner identical to that described above. More generally, the program(s) may be loaded into one of the storage means of the computer 600 before being executed.

The central processing unit 605 will control and direct the execution of the instructions or portions of software code of the program(s) according to an embodiment, instructions that are stored, for example, in the read only memory 615 or in the other aforementioned storage elements. When powering on, the program(s) that are stored in a non-volatile memory, for example the read only memory 615, are transferred into the random access memory 610 that then contains the executable code of the program(s), as well as registers for storing the variables and parameters necessary for implementing the method according to an embodiment.

Of course, the claims are not limited to the embodiments described above by way of examples. They extend to other alternative embodiments.

Depending on the embodiment chosen, certain acts, actions, events or functions of each of the methods described in the present document may be carried out or occur according to an order different to that in which they have been described, or may be added, merged or even not be carried out or not occur, depending on the case. Furthermore, in certain embodiments, certain acts, actions or events are carried out or occur concurrently and not successively.

Although described through a certain number of detailed embodiments, the device, the system and the method proposed comprise various alternative embodiments, modifications and improvements that will become apparent to the person skilled in the art, it being understood that these various alternative embodiments, modifications and improvements fall within the scope of the following claims. In addition, various aspects and features described above may be implemented together, or separately, or substitute one another, and all of the various combinations and subcombinations of the aspects and features fall within the scope of the claims. Furthermore, it may be that certain systems and equipment described above may not incorporate all of the modules and functions described for the preferred embodiments.

What is claimed is:

1. A testing device comprising:
at least one first communication interface for receiving data from an electronic system to be tested and transmitting data to the electronic system; and
at least one second communication interface, distinct from the first communication interface, for transmitting data to a test computer of the electronic system;
wherein the testing device is configured to:
receive at least one first item of data from the electronic system and/or transmit at least one second item of data to the electronic system, via a first communication bus connected to the first communication interface, autonomously; and
transmit, via a second communication bus connected to the second communication interface, at least one representative item of data representative of the at least one first item of data received and/or of the at least one second item of data transmitted via the first communication bus.

2. The testing device according to claim 1, wherein the received at least one first item of data is a request, and wherein the testing device is configured to transmit the at least one second item of data to the electronic system in response to the request.

3. The testing device according to claim 1, further comprising:
a memory for storing the at least one representative item of data to be transmitted; and
a data processing unit for determining the at least one representative item of data to be transmitted.

4. The testing device according to claim 1, further comprising a selector for transmitting the at least one first item of data and/or the at least one second item of data to the electronic system via the first communication bus.

5. The testing device according to claim 1, wherein the testing device is configured to carry out multiple iterations of the receive and transmit, without manual intervention, on an application embedded in the electronic system.

6. An integrated assembly comprising:
the testing device according to claim 1; and
the electronic system to be tested.

7. The integrated assembly according to claim 6, wherein the testing device is configured to carry out multiple iterations of the receive and transmit, without manual intervention, on an application embedded in the electronic system.

8. A method for testing an application embedded in an electronic system, the electronic system connected, via a first communication bus, to a testing device, the testing device connected to a test computer via a second communication bus distinct from the first communication bus, the method comprising:
detecting, by the testing device, an event for transmitting at least one second item of data to the electronic system via the first communication bus;
determining, by the testing device, the at least one second item of data to be transmitted;
first transmitting, by the testing device to the electronic system, the at least one second item of data via the first communication bus; and
second transmitting, by the testing device to the test computer, via the second communication bus, at least one representative item of data representative of at least one first item of data received from the electronic system via the first communication bus and/or the at least one second item of data transmitted to the electronic system via the first communication bus.

9. The method according to claim 8, further comprising receiving the at least one first item of data from the electronic system.

10. The method according to claim 9, wherein the received at least one first item of data is a request, and the method further comprises transmitting the at least one second item of data to the electronic system in response to the request.

11. The method according to claim 8, further comprising:
storing, in a memory of the testing device, the at least one representative item of data to be transmitted; and
determining, by a data processing unit of the testing device, the at least one representative item of data to be transmitted.

12. The method according to claim 8, further comprising transmitting, by a selector of the testing device, the at least one first item of data and/or the at least one second item of data to the electronic system via the first communication bus.

13. The method according to claim 8, further comprising carrying out multiple iterations of the detecting, determining, first transmitting, and second transmitting, without manual intervention, on an application embedded in the electronic system.

14. A method for testing an application embedded in an electronic system, the electronic system connected, via a first communication bus, to a testing device, the testing device connected to a test computer via a second communication bus, the method comprising:
first transmitting, by the test computer to the testing device, at least one configuration instruction to transmit at least one second item of data to the electronic system, the at least one configuration instruction comprising at least one selection indication to select the at least one second item of data to be transmitted to the electronic system via the first communication bus; and
second transmitting, by the test computer to the testing device, at least one read instruction to receive, via the second communication bus, at least one representative item of data representative of at least one first item of data received from the electronic system via the first communication bus and/or at least one second item of data transmitted to the electronic system via the first communication bus.

15. The method according to claim 14, further comprising repeating the second transmitting of the at least one read instruction according to a test scenario of the embedded application.

16. The method according to claim 15, further comprising carrying out the first transmitting of the at least one configuration instruction before the repeated second transmitting of the read instructions.

17. The method according to claim 14, further comprising receiving the at least one representative item of data representative of the at least one first item of data received from the electronic system via the first communication bus and/or the at least one second item of data transmitted to the electronic system via the first communication bus.

18. The method of claim 17, further comprising comparing the at least one representative item of data representative of the at least one first item of data received from the electronic system via the first communication bus and/or the at least one second item of data transmitted to the electronic system via the first communication bus with an expected item of data.

19. The method of claim 18, further comprising storing the at least one representative item of data and the expected item of data.

20. The method of claim 19, further comprising generating a test report for the electronic system based on the at least one representative item of data and the expected item of data.
